(19) United States
(12) Patent Application Publication
(10) Pub. No.: US 2022/0020661 A1
(43) Pub. Date: Jan. 20, 2022

(54) POWER CONVERSION DEVICE

(71) Applicant: Mitsubishi Electric Corporation, Tokyo (JP)

(72) Inventor: Masakazu TANI, Tokyo (JP)

(73) Assignee: Mitsubishi Electric Corporation, Tokyo (JP)

(21) Appl. No.: 17/187,185

(22) Filed: Feb. 26, 2021

(30) Foreign Application Priority Data
Jul. 17, 2020 (JP) 2020-122580

(51) Int. Cl. H01L 23/367; H01L 23/473; H01G 2/08; H01G 2/10; H02M 7/537

(52) U.S. Cl. CPC H01L 23/3675; H01L 23/473; H02M 7/537; H01G 2/10; H01G 2/08

(57) ABSTRACT

A power conversion device includes: a power semiconductor module; a capacitor; a heatsink; cooling fins; a first partition; a cooling flow path through which a coolant flows between the heatsink and the first partition; a second partition extending from the first partition; an inflow path extending from a coolant inlet along another surface of the first partition and a surface of the second partition on a first side surface side, and connected to a first side surface side of the cooling flow path; and an outflow path extending from a coolant outlet along the other surface of the first partition and a surface of the second partition on a second side surface side, and connected to a second side surface side of the cooling flow path, wherein a length of the first side surface of the power semiconductor module is greater than a length of the third side surface thereof.

### BACKGROUND OF THE INVENTION

### 1. Field of the Invention

The present disclosure relates to a power conversion device.

### 2. Description of the Background Art

In an electric vehicle using a motor as a drive source as in an electric automobile or a hybrid automobile, a plurality of power conversion devices are mounted. The power conversion device is a device for converting input current from DC to AC or from AC to DC or for converting input voltage to different voltage. As specific examples, there are a charger which converts commercial AC power to DC power to charge a high-voltage battery, a DC/DC converter for converting DC power of a high-voltage battery to voltage (e.g., 12 V) for a battery for an auxiliary device, an inverter for converting DC power from a battery to AC power for a motor, and the like.

The power conversion devices mounted on an electric automobile or a hybrid automobile are required to have reduced sizes and increased outputs. With increase in output of the power conversion device, a power semiconductor module and a capacitor stored in the power conversion device are subjected to large current, so that the amount of heat generated in the power semiconductor module and the capacitor increases. Therefore, the power conversion device is provided with a cooling structure for cooling the power semiconductor module and the capacitor by a coolant.

As a power conversion device, for example, disclosed is a structure in which a power semiconductor module and a capacitor are arranged close to each other in a hollow housing, and a cooling passage through which a coolant flows is provided directly under the power semiconductor module (see, for example, Patent Document 1). In the disclosed structure, the cooling passage is provided so that the coolant flows in the longitudinal direction of the power semiconductor module and the capacitor which are cooling targets.

Patent Document 1: Japanese Laid-Open Patent Publication No. 2017-135901

In Patent Document 1, the cooling passage is provided close to the capacitor and the power semiconductor module, whereby the capacitor and the power semiconductor module can be cooled. However, since the coolant flows in the longitudinal direction of the power semiconductor module, the cooling passage is elongated in the longitudinal direction of the power semiconductor module, and thus the fluid resistance in the cooling passage increases. In addition, if cooling fins are provided to the cooling passage in order to increase heat dissipation of the power semiconductor module, the fluid resistance in the cooling passage further increases. Since there is a limit on the pump-out pressure of a water pump for supplying the coolant to the cooling passage, it is necessary to expand the pitch intervals of the cooling fins to reduce the fluid resistance. In the case where the cooling passage is provided in the longitudinal direction of the power semiconductor module, the occupation rate of the cooling fins is decreased, thus causing a problem of reducing heat dissipation of the power semiconductor module.

In addition, since the coolant flows in the longitudinal direction of the power semiconductor module to cool the power semiconductor module, the coolant has a low temperature on the upstream side of the cooling passage and has a high temperature on the downstream side, and thus a temperature difference occurs between the upstream side and the downstream side of the power semiconductor module. As a result, due to the temperature characteristics present on the upstream side and the downstream side of the power semiconductor module, a difference occurs in electric characteristics on the upstream side and the downstream side, thus causing a problem of deteriorating controllability of the power semiconductor module.

### SUMMARY OF THE INVENTION

In view of the above, an object of the present disclosure is to obtain a power conversion device that can improve heat dissipation of a power semiconductor module and can uniform the heat dissipation irrespective of the locations on the power semiconductor module.

A power conversion device according to the present disclosure includes: a power semiconductor module including a power semiconductor, the power semiconductor module being formed in a rectangular parallelepiped shape and having a bottom surface, a top surface, and four side surfaces; a capacitor electrically connected to the power semiconductor module, and provided on a first side surface side of the power semiconductor module or on a second side surface side thereof opposite to the first side surface; a plate-shaped heatsink whose one surface is thermally connected to the bottom surface of the power semiconductor module; a cooling fin provided to another surface of the heatsink; a plate-shaped first partition provided such that one surface thereof is opposed to the other surface of the heatsink with the cooling fin therebetween; a cooling flow path through which a coolant flows in a direction perpendicular to the first side surface, in a space in which the cooling fin is placed between the other surface of the heatsink and the one surface of the first partition; a plate-shaped second partition extending from another surface of the first partition in a direction away from the other surface, and extending from a third side surface side adjacent to the first side surface of the power semiconductor module, to a fourth side surface side thereof opposite to the third side surface; an inflow path extending from a coolant inlet provided on the third side surface side or the fourth side surface side, along the other surface of the first partition and a surface of the second partition on the first side surface side, the inflow path being connected to a part on the first side surface side of the cooling flow path; and an outflow path extending from a coolant outlet provided on the third side surface side or the fourth side surface side, along the other surface of the first partition and a surface of the second partition on the second side surface side, the outflow path being connected to a part on the second side surface side of the cooling flow path, wherein a length of the first side surface of the power semiconductor module is greater than a length of the third side surface thereof.

The power conversion device according to the present disclosure includes: the cooling flow path through which the coolant flows in the direction perpendicular to the first side surface of the power semiconductor module, in the space between the other surface of the heatsink and the one surface of the first partition; the inflow path extending from the coolant inlet along the other surface of the first partition and the surface of the second partition on the first side surface side, and connected to the part on the first side surface side of the cooling flow path; and the outflow path extending from the coolant outlet along the other surface of the first partition and the surface of the second partition on the second side surface side, and connected to the part on the second side surface side of the cooling flow path, wherein the length of the first side surface of the power semiconductor module is greater than the length of the third side surface thereof. Thus, the coolant flows in the short-side direction of the power semiconductor module, so that the fluid resistance in the cooling flow path is reduced. Therefore, it is possible to increase the occupation rate of the cooling fins and improve heat dissipation of the power semiconductor module. In addition, since the coolant flows in the short-side direction of the power semiconductor module, heat dissipation of the power semiconductor module can be uniformed irrespective of locations on the power semiconductor module.

### BRIEF DESCRIPTION OF THE DRAWINGS

FIG. 1 shows a circuit configuration of an inverter of a power conversion device according to the first embodiment of the present disclosure;

FIG. 2 is a perspective view schematically showing the outer appearance of the power conversion device according to the first embodiment;

FIG. 3 is a side view of the power conversion device according to the first embodiment;

FIG. 4 is a sectional view of a specific part of the power conversion device, taken at an A-A cross-section position in FIG. 2;

FIG. 5 is a sectional view of a specific part of the power conversion device, taken at a B-B cross-section position in FIG. 3;

FIG. 6 is a sectional view of a specific part of the power conversion device, taken at a C-C cross-section position in FIG. 3;

FIG. 7 is a sectional view of a specific part of the power conversion device, taken at a D-D cross-section position in FIG. 3;

FIG. 8 schematically shows a structure of a power semiconductor module of the power conversion device according to the first embodiment;

FIG. 9 is a sectional view of a specific part of another power conversion device, taken at a B-B cross-section position in FIG. 3;

FIG. 10 is a sectional view schematically showing a specific part of a power conversion device according to the second embodiment of the present disclosure;

FIG. 11 is a sectional view schematically showing a specific part of the power conversion device according to the second embodiment;

FIG. 12 is a sectional view schematically showing a specific part of the power conversion device according to the second embodiment;

FIG. 13 is a sectional view schematically showing a specific part of the power conversion device according to the second embodiment;

FIG. 14 schematically shows a structure of a power semiconductor module of the power conversion device according to the second embodiment;

FIG. 15 is a sectional view schematically showing a specific part of a power conversion device according to the third embodiment of the present disclosure;

FIG. 16 is a sectional view schematically showing a specific part of the power conversion device according to the third embodiment;

FIG. 17 is a sectional view schematically showing a specific part of the power conversion device according to the third embodiment; and

FIG. 18 is a sectional view schematically showing a specific part of the power conversion device according to the third embodiment.

### DETAILED DESCRIPTION OF THE PREFERRED EMBODIMENTS OF THE INVENTION

Hereinafter, a power conversion device according to embodiments of the present disclosure will be described with reference to the drawings. In the drawings, the same or corresponding members or parts are denoted by the same reference characters.

### First Embodiment

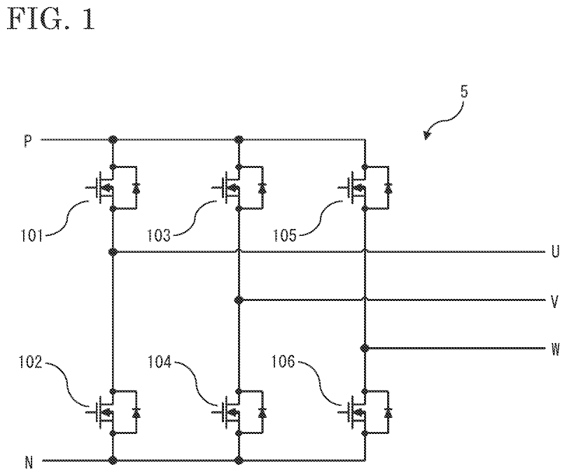

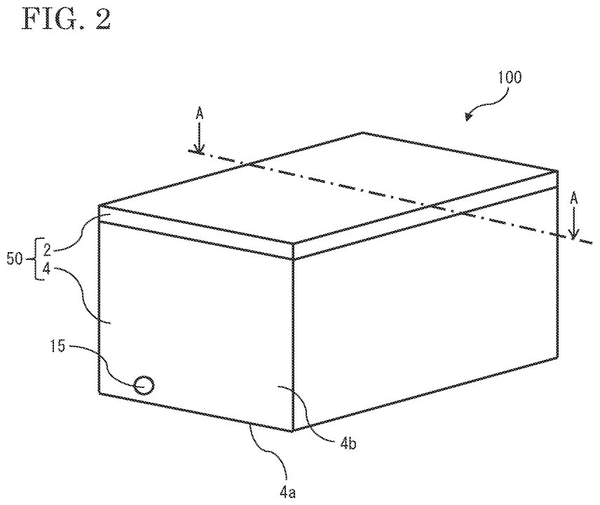

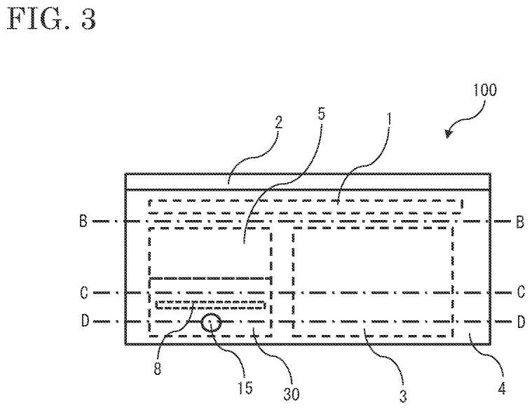

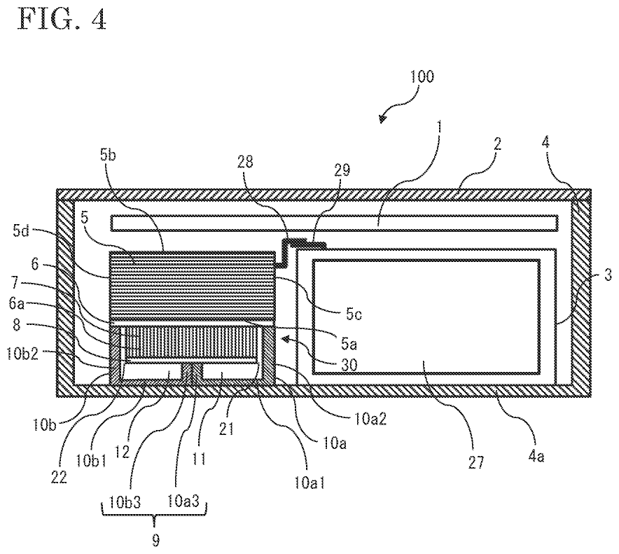

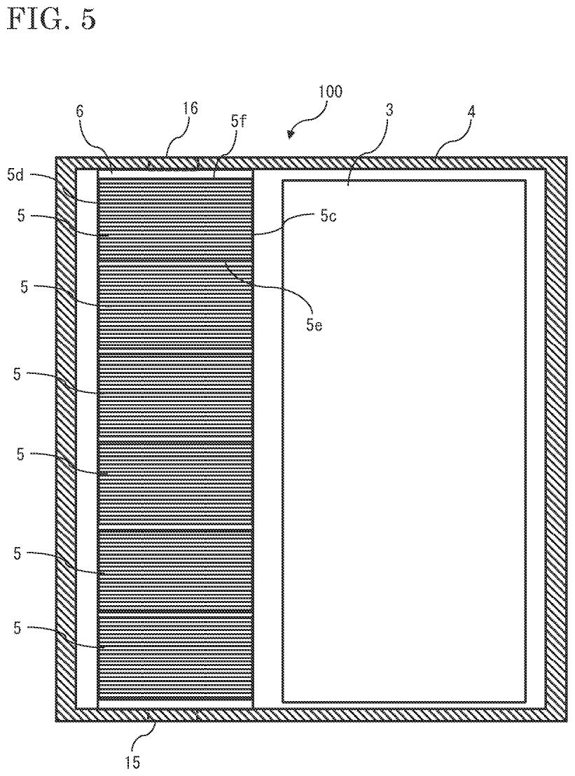

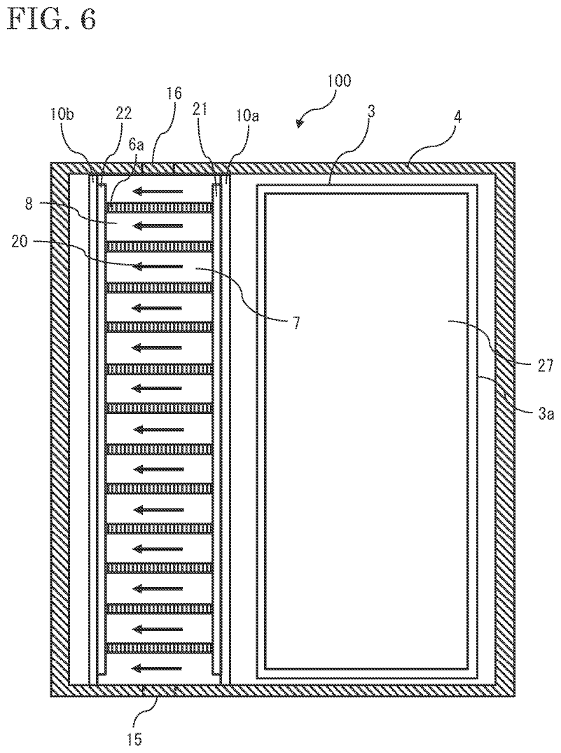

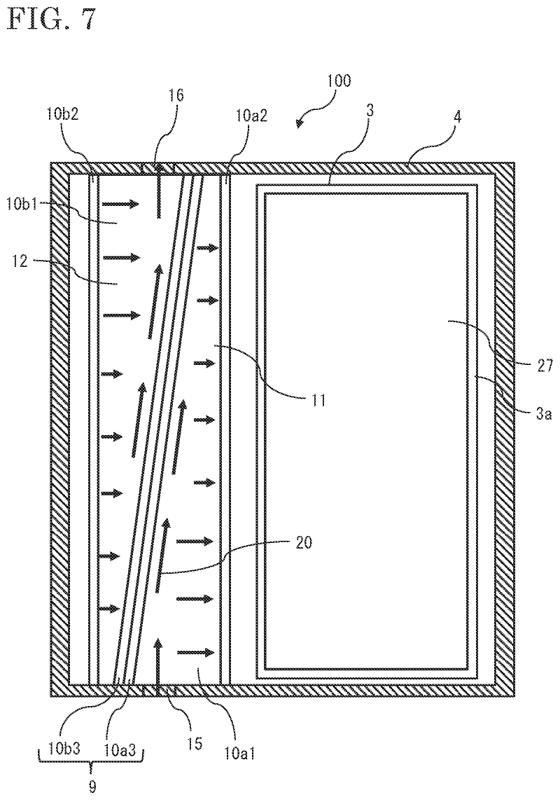

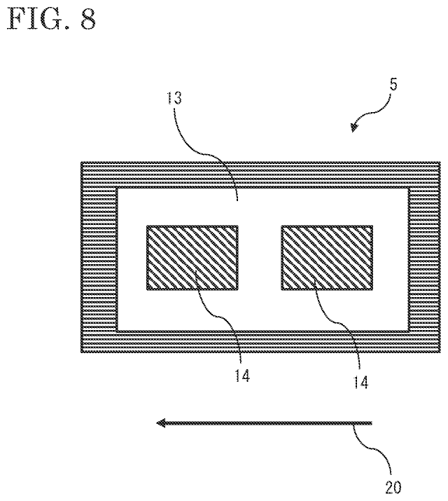

FIG. 1 shows a circuit configuration of an inverter of a power conversion device 100 according to the first embodiment of the present disclosure, FIG. 2 is a perspective view schematically showing the outer appearance of the power conversion device 100, FIG. 3 is a side view of the power conversion device 100, FIG. 4 is a sectional view of a specific part of the power conversion device 100, taken at an A-A cross-section position in FIG. 2, FIG. 5 is a sectional view of a specific part of the power conversion device 100, taken at a B-B cross-section position in FIG. 3, FIG. 6 is a sectional view of a specific part of the power conversion device 100, taken at a C-C cross-section position in FIG. 3, FIG. 7 is a sectional view of a specific part of the power conversion device 100, taken at a D-D cross-section position in FIG. 3, and FIG. 8 schematically shows a structure of a power semiconductor module 5 of the power conversion device 100. In FIG. 3, some of components stored inside a case 4 of the power conversion device 100 are represented by broken lines. The power conversion device 100 includes a switching circuit for controlling power, and converts input current from DC to AC or from AC to DC or converts input voltage to different voltage.

<Circuit Configuration of Power Conversion Device 100>

The power conversion device 100 corresponds to an electric power component such as a motor driving inverter mounted on an electric vehicle such as an electric automobile or a hybrid automobile, a step-down converter which performs conversion from high voltage to low voltage, or a charger which is connected to external power supply equipment and charges an on-vehicle battery. Using the motor driving inverter as an example, a circuit configuration of the power conversion device 100 will be described with reference to FIG. 1. The motor driving inverter includes a power semiconductor module 5, converts supplied DC current to AC currents, and supplies the converted AC currents for three phases (U phase, V phase, W phase) to a motor (not shown) which is a load. The motor is driven by the supplied three-phase AC currents. A capacitor (not shown in FIG. 1) for smoothing DC current is connected to the power semiconductor module 5.

The three phases, i.e., U phase, V phase, W phase, are each formed by two arms, i.e., an upper arm 101, 103, 105 and a lower arm 102, 104, 106. Each arm is formed by a power semiconductor. The power semiconductor is, for example, a metal-oxide-semiconductor field-effect transistor (MOSFET), an insulated gate bipolar transistor (IGBT), or a diode. The power semiconductor is for controlling rated current of several amperes to several hundred amperes. As the material of the power semiconductor elements, not only silicon (Si) but also a next-generation semiconductor such as silicon carbide (SiC) or gallium nitride (GaN) may be used.

<Component Structure of Power Conversion Device 100>

In the power conversion device 100, as shown in FIG. 2, a housing 50 is formed by a cover 2 and the case 4. In FIG. 2, openings relevant to electric input and output of the power conversion device 100 are not shown. The case 4 includes a bottom plate 4a having a rectangular plate shape, and side portions 4b extending from four side surfaces of the bottom plate 4a in the direction perpendicular to the plate surface of the bottom plate 4a. One of the side portions 4b is provided with a coolant inlet 15 through which a coolant flows in. In addition, the side portion 4b on the side opposite to the side portion 4b provided with the coolant inlet 15 is provided with a coolant outlet 16 (not shown in FIG. 2) through which the coolant flows out. In the present embodiment, the coolant inlet 15 and the coolant outlet 16 are provided in different side portions 4b. However, these may be provided in the same side portion 4b. In addition, arrangement of the coolant inlet 15 and the coolant outlet 16 may be reversed.

As shown in FIG. 4, the power conversion device 100 includes the power semiconductor module 5, a capacitor 3, a control board 1, and a cooling device 30. The power semiconductor module 5 has a rectangular parallelepiped shape having a bottom surface 5a, a top surface 5b, and four side surfaces (first side surface 5c, second side surface 5d, third side surface 5e, fourth side surface 5f), and has a power semiconductor 14 therein. In the present embodiment, as shown in FIG. 5, six power semiconductor modules 5 are arranged side by side in the direction parallel to the first side surfaces 5c so as to be directed in the same direction. The bottom surfaces 5a of all the power semiconductor modules 5 are thermally connected to one surface of a heatsink 6. The number of the power semiconductor modules 5 is not limited to six, and may be one. In the power semiconductor module 5, for example, as shown in FIG. 8, two power semiconductors 14 are mounted to one substrate 13 provided inside. The structure of the substrate 13 is not limited thereto, and a structure in which one or a plurality of power semiconductors 14 are mounted on each of a plurality of substrates 13, may be employed.

The capacitor 3 is a part formed by storing an element component 27 in a capacitor case 3a and injecting resin (not shown) into a gap between the element component 27 and the capacitor case 3a. The capacitor 3 is attached to the bottom plate 4a of the case 4 via a thermal interface material such as grease by screwing, for example. The capacitor 3 is electrically connected to the power semiconductor modules 5, and is provided on the first side surface 5c side of the six power semiconductor modules 5 or on the second side surface 5d side opposite to the first side surface 5c side, so as to be opposed to the first side surface 5c side or the second side surface 5d side of the six power semiconductor modules 5. In the present embodiment, the capacitor 3 is provided on the first side surface 5c side. The length on the first side surface 5c side obtained by summing lengths in the longitudinal direction of the first side surfaces 5c of the six power semiconductor modules 5 is greater than the length on the third side surface 5e side adjacent to the first side surface 5c. The longitudinal-direction surface of the capacitor 3 is opposed to the first side surface 5c side of the power semiconductor modules 5. The control board 1 is electrically connected to the power semiconductor modules 5, and outputs signals for controlling operations of the power semiconductor modules 5, thereby controlling operations of the power semiconductor modules 5.

The cooling device 30 has a flow path which is connected to the coolant inlet 15 and the coolant outlet 16 and through which a coolant flows. The details of the flow path will be described later. The cooling device 30 cools the power semiconductor module 5 and the capacitor 3. As the coolant, for example, water or an ethylene glycol solution is used. The cooling device 30 includes the heatsink 6, cooling fins 6a, a first partition 8, a first water jacket 10a, a second water jacket 10b, and a second partition 9. The second partition 9 is formed by a part of the first water jacket 10a and a part of the second water jacket 10b.

The heatsink 6 has a plate shape, and one surface thereof is thermally connected to the bottom surface 5a of the power semiconductor module 5. The cooling fins 6a are provided on the other surface of the heatsink 6. The heatsink 6 and the cooling fins 6a are made of metal such as aluminum having a high thermal conductivity. If the occupation rate of the cooling fins 6a is increased, the area of contact between the coolant and the cooling fins 6a increases, so that heat dissipation of the power semiconductor module 5 can be improved. Meanwhile, the increase in the occupation rate of the cooling fins 6a reduces the sectional area of the flow path through which the coolant flows. The reduction of the sectional area of the flow path increases the fluid resistance of the coolant, and thus it becomes necessary to enhance the performance of a water pump which is a motive power source for the coolant to flow, leading to cost increase. In the present embodiment, as described later, the coolant flows in a short-side direction of the entirety of the six power semiconductor modules 5, which is a direction perpendicular to the first side surface 5c. Thus, increase in the fluid resistance can be suppressed.

The first partition 8 has a plate shape, and one surface thereof is opposed to the other surface of the heatsink 6 with the cooling fins 6a therebetween. The first partition 8 is provided with an inflow penetration portion 21 along an end on the first side surface 5c side of the first partition 8, and an outflow penetration portion 22 along an end on the second side surface 5d side of the first partition 8. The second partition 9 has a plate shape. The second partition 9 extends from the other surface of the first partition 8 in a direction away from the other surface, and extends from the third side surface 5e side adjacent to the first side surface 5c of the power semiconductor module 5, to the fourth side surface 5f side opposite to the third side surface 5e side. The second partition 9 extends so as to approach the first side surface 5c side from the second side surface 5d side, as approaching the fourth side surface 5f side from the third side surface 5e.

The first water jacket 10a and the second water jacket 10b are members for forming the flow path together with the heatsink 6 and the first partition 8. The first water jacket 10a has a quadrangular plate-shaped first bottom portion 10a1, a rectangular plate-shaped first side wall 10a2 extending from a first side surface of the first bottom portion 10a1 in the direction perpendicular to the plate surface of the first bottom portion 10a1, and a rectangular plate-shaped second side wall 10a3 having a smaller height than the first side wall 10a2 and extending from a second side surface of the first bottom portion 10a1 opposite to the first side surface, in the direction perpendicular to the plate surface of the first bottom portion 10a1, so as to be opposed to the first side wall 10a2. The second water jacket 10b has a quadrangular plate-shaped second bottom portion 10b1, a rectangular plate-shaped third side wall 10b2 extending from a first side surface of the second bottom portion 10b1 in the direction perpendicular to the plate surface of the second bottom portion 10b1, and a rectangular plate-shaped fourth side wall 10b3 having a smaller height than the third side wall 10b2 and extending from a second side surface of the second bottom portion 10b1 opposite to the first side surface, in the direction perpendicular to the plate surface of the second bottom portion 10b1, so as to be opposed to the third side wall 10b2. The first bottom portion 10a1 of the first water jacket 10a and the second bottom portion 10b1 of the second water jacket 10b are attached to the bottom plate 4a of the case 4.

Both outer wall surfaces of the second side wall 10a3 and the fourth side wall 10b3 are in contact with each other so that the second partition 9 is formed by the second side wall 10a3 and the fourth side wall 10b3. A side surface of the second side wall 10a3 opposite to a side surface thereof on the first bottom portion 10a1 side, and a side surface of the fourth side wall 10b3 opposite to a side surface thereof on the second bottom portion 10b1 side, are joined to the other surface of the first partition 8. A side surface of the first side wall 10a2 opposite to a side surface thereof on the first bottom portion 10a1 side, and a side surface of the third side wall 10b2 opposite to a side surface thereof on the second bottom portion 10b1 side, are joined to the other surface of the heatsink 6. The first partition 8, the first water jacket 10a, and the second water jacket 10b are made of metal, for example. The first side wall 10a2 and the third side wall 10b2 are joined to the other surface of the heatsink 6 by friction stirring, for example. In the case where these are joined by friction stirring, water-tightness of the cooling device 30 can be ensured. By a part of the first water jacket 10a and a part of the second water jacket 10b, the second partition 9 is formed, and the flow path described later is formed, whereby productivity of the power conversion device 100 can be improved and the power conversion device 100 can be manufactured at low cost.

<Configuration of Electric Wiring in Power Conversion Device 100>

In the present embodiment, as shown in FIG. 8, one power semiconductor module 5 is formed in one substrate unit and one arm is formed with one substrate. The six arms shown in FIG. 1 are formed by six power semiconductor modules 5. The control board 1 electrically connected to the power semiconductor modules 5 is provided so as to be opposed to the top surface 5b of the power semiconductor module 5 and the capacitor 3. A power terminal 28 exposed to outside from the power semiconductor module 5 and a power terminal 29 exposed to outside from the capacitor 3 are electrically connected to each other between the control board 1, and the power semiconductor module 5 and the capacitor 3. The power terminal 28 and the power terminal 29 are, for example, metal bus bars. The power terminal 28 and the power terminal 29 are connected by, for example, welding, screw tightening, or laser welding.

The capacitor 3 is provided close to the power semiconductor module 5. In order to improve power conversion efficiency of the power semiconductor 14, it is necessary to shorten metal bus bars that are electric wires between the power semiconductor module 5 and the capacitor 3 so as to reduce a parasitic inductance and a parasitic capacitance. In the power semiconductor 14, voltage surge occurs at the time of switching. The voltage surge is determined by a product of a switching speed (change rate of current) and a parasitic inductance of the metal bus bar. The voltage surge is restricted due to the withstand voltage of the power semiconductor 14, and therefore, if the parasitic inductance is reduced, the switching speed can be increased and switching loss in the power semiconductor 14 is reduced, whereby power conversion efficiency can be improved. Since the capacitor 3 and the power semiconductor module 5 are arranged close to each other, the parasitic inductance and the parasitic capacitance can be reduced. In addition, in the case where the power terminal 28 and the power terminal 29 are connected to each other between the control board 1, and the power semiconductor module 5 and the capacitor 3, the length of the electric wires between the capacitor 3 and the power semiconductor module 5 can be minimized.

<Structure of Flow Path in Cooling Device 30>

The structure of the flow path in the cooling device 30, which is a major part of the present disclosure, will be described. As shown in FIG. 4, the flow path in the cooling device 30 is composed of a cooling flow path 7, an inflow path 11, and an outflow path 12. The cooling flow path 7 is provided above the inflow path 11 and the outflow path 12, and thus the flow path is formed in two stages.

The cooling flow path 7 is a space where the cooling fins 6a are provided between the other surface of the heatsink 6 and the one surface of the first partition 8, and as shown in FIG. 6, the coolant flows in a direction perpendicular to the first side surface 5c. Arrows shown in the drawing indicate flow directions 20 representing directions in which the coolant flows. The cooling fins 6a are formed along the flow directions 20. The number of the cooling fins 6a is not limited to the number shown in the drawing, and may be set within such a range that does not extremely increase the fluid resistance of the coolant. When the coolant flows through the cooling flow path 7, the cooling fins 6a and the heatsink 6 are cooled. As the cooling fins 6a and the heatsink 6 are cooled, the power semiconductor modules 5 are also cooled. The inflow path 11 extends from the coolant inlet 15 provided on the third side surface 5e side, along the other surface of the first partition 8 and a surface of the second partition 9 on the first side surface 5c side, and is connected to a part on the first side surface 5c side of the cooling flow path 7. The cooling flow path 7 and the inflow path 11 are connected via the inflow penetration portion 21. The outflow path 12 extends from the coolant outlet 16 provided on the fourth side surface 5f side, along the other surface of the first partition 8 and a surface of the second partition 9 on the second side surface 5d side, and is connected to a part on the second side surface 5d side of the cooling flow path 7. The cooling flow path 7 and the outflow path 12 are connected via the outflow penetration portion 22. In the present embodiment, since the capacitor 3 is provided on the first side surface 5c side, the capacitor 3 is close to the inflow path 11. The coolant inlet 15 and the coolant outlet 16 are provided in different side portions 4b so as to be opposed to each other, and the inflow path 11 and the outflow path 12 are partitioned from each other by the second partition 9. Thus, the inflow path 11 and the outflow path 12 can be made the same in the flow path length and the flow path width in which the coolant flows, and the flow speed of the coolant can be kept uniform.

As shown in FIG. 7, the coolant flows from the coolant inlet 15 into the inflow path 11. In the inflow path 11, the second partition 9 extends so as to approach the first side surface 5c side from the second side surface 5d side, as approaching the fourth side surface 5f side from the third side surface 5e side. Thus, the inflow path 11 is formed such that the sectional area thereof reduces in the direction in which the coolant flows. Therefore, the flow speed of the coolant is not slowed down even at a part far from the coolant inlet 15. The coolant flows from the inflow path 11 into the cooling flow path 7 via the inflow penetration portion 21. The coolant having passed between the cooling fins 6a flows from the cooling flow path 7 into the outflow path 12 via the outflow penetration portion 22. The outflow path 12 is formed such that the sectional area thereof increases toward the coolant outlet 16. Therefore, the flow speed of the coolant is not slowed down even at a part far from the coolant outlet 16. The coolant having passed through the flow path in the cooling device 30 is discharged to outside from the coolant outlet 16. The temperature of the coolant flowing through the flow path in the cooling device 30 is low in the inflow path 11 before the coolant passes through the cooling flow path 7, and is high in the outflow path 12 after the coolant passes through the cooling flow path 7. At the power semiconductor module 5, the flow direction 20 of the coolant is the direction of an arrow shown in FIG. 8.

With the above structure, the coolant can flow in the short-side direction of the entirety of the six power semiconductor modules 5. Thus, increase in the fluid resistance can be suppressed, and therefore the occupation rate of the cooling fins 6a need not be decreased and the cooling fins 6a are arranged with a high density, so that heat dissipation of the power semiconductor modules 5 can be improved. In addition, since the coolant flows in parallel among the six power semiconductor modules 5, a temperature difference does not occur among the six power semiconductor modules 5. Thus, heat dissipation of the six power semiconductor modules 5 can be uniformed irrespective of the locations. Since heat dissipation of the six power semiconductor modules 5 can be uniformed, electric characteristics of the six power semiconductor modules 5 having temperature characteristics are uniformed among the six power semiconductor modules 5, whereby switching controllability of the power conversion device 100 can be improved.

Since the capacitor 3 is provided close to the inflow path 11 in which the temperature of the coolant is low, the capacitor 3 can be cooled at the initial temperature of the coolant flowing into the coolant inlet 15, so that the capacitor 3 which is thermally weak can be cooled by the coolant on the low-temperature side. The cooling flow path 7 is provided above the inflow path 11 and the outflow path 12, and the power semiconductor modules 5 are provided above the cooling flow path 7, so that there are no flow paths around the side surfaces of the power semiconductor modules 5. Therefore, the capacitor 3 can be provided close to the power semiconductor modules 5. Since the capacitor 3 can be provided close to the power semiconductor modules 5, the power semiconductor modules 5 and the capacitor 3 can be wired by metal bus bars with the shortest distance. Thus, the parasitic inductances on the metal bus bars are reduced, whereby the power semiconductors 14 of the power semiconductor modules 5 can perform high-speed switching operations.

The sum of the height of the power semiconductor module 5 and the height of the cooling device 30 coincides with the height of the capacitor 3. Therefore, a dead space inside the case 4 is reduced, so that the power conversion device 100 can be downsized. In addition, since the height of the power semiconductor module 5 and the height of the capacitor 3 coincide with each other, electric wires between the power semiconductor module 5 and the capacitor 3 can be made in the shortest distance, whereby it is possible to achieve reduction of the inductance of the power conversion device 100 in addition to size reduction of the power conversion device 100.

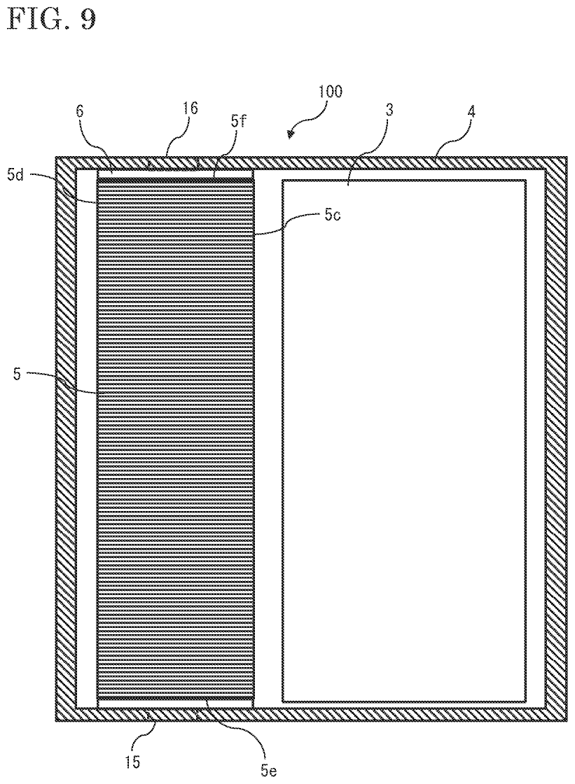

In the case where the power conversion device 100 has one power semiconductor module 5, as shown in FIG. 9, the length of the first side surface 5c of the power semiconductor module 5 is greater than the length of the third side surface 5e. In FIG. 9, the capacitor 3 is provided on the first side surface 5c side. The coolant flows in the direction perpendicular to the first side surface 5c, as in the case of FIG. 6. Thus, the coolant can flow in the short-side direction of the power semiconductor module 5.

As described above, the power conversion device 100 according to the first embodiment includes: the cooling flow path 7 through which the coolant flows in the direction perpendicular to the first side surface 5c of the power semiconductor module 5, in a space between the other surface of the heatsink 6 and the one surface of the first partition 8; the inflow path 11 extending from the coolant inlet 15 along the other surface of the first partition 8 and the surface of the second partition 9 on the first side surface 5c side, and connected to a part on the first side surface 5c side of the cooling flow path 7; and the outflow path 12 extending from the coolant outlet 16 along the other surface of the first partition 8 and the surface of the second partition 9 on the second side surface 5d side, and connected to a part on the second side surface 5d side of the cooling flow path 7, wherein the length of the first side surface 5c of the power semiconductor module 5 is greater than the length of the third side surface 5e thereof. Thus, the coolant flows in the short-side direction of the power semiconductor module 5, so that the fluid resistance in the cooling flow path 7 is reduced. Therefore, it is possible to increase the occupation rate of the cooling fins 6a and improve heat dissipation of the power semiconductor module 5. In addition, since the coolant flows in the short-side direction of the power semiconductor module 5, heat dissipation of the power semiconductor module 5 can be uniformed irrespective of locations on the power semiconductor module 5.

In the case where a plurality of power semiconductor modules 5 are arranged side by side in the direction parallel to the first side surfaces 5c so as to be directed in the same direction, the capacitor 3 is provided on the first side surface 5c side of the plurality of power semiconductor modules 5 so as to be opposed to the first side surfaces 5c of the plurality of power semiconductor modules 5, and the length on the first side surface 5c side of the plurality of power semiconductor modules 5 is greater than the length on the third side surface 5e side thereof, the coolant flows in the short-side direction of the plurality of power semiconductor modules 5, so that the fluid resistance in the cooling flow path 7 is reduced. Therefore, it is possible to increase the occupation rate of the cooling fins 6a and improve heat dissipation of the plurality of power semiconductor modules 5. In addition, since the coolant flows in the short-side direction of the plurality of power semiconductor modules 5, heat dissipation of the plurality of power semiconductor modules 5 can be uniformed irrespective of locations on the plurality of power semiconductor modules 5.

In the case where the coolant inlet 15 is provided on the third side surface 5e side of the power semiconductor module 5, the coolant outlet 16 is provided on the fourth side surface 5f side of the power semiconductor module 5, and the second partition 9 extends so as to approach the first side surface 5c side from the second side surface 5d, as approaching the fourth side surface 5f side from the third side surface 5e side, the inflow path 11 and the outflow path 12 can be made the same in the flow path length and the flow path width in which the coolant flows, and the flow speed of the coolant can be kept uniform.

In the case where the second partition 9 is formed by a part of the first water jacket 10a and a part of the second water jacket 10b, and the inflow path 11 and the outflow path 12 are formed by the first water jacket 10a and the second water jacket 10b, productivity of the power conversion device 100 can be improved and the power conversion device 100 can be manufactured at low cost. In the case where the first bottom portion 10a1 of the first water jacket 10a, the second bottom portion 10b1 of the second water jacket 10b, and the capacitor 3 are attached to the bottom plate 4a of the case 4, productivity of the power conversion device 100 can be improved and the power conversion device 100 can be manufactured at low cost.

In the case where the capacitor 3 is provided on the first side surface 5c side on which the inflow path 11 is provided, the capacitor 3 is close to the inflow path 11 in which the temperature of the coolant is low. Thus, the capacitor 3 can be cooled at the initial temperature of the coolant flowing into the coolant inlet 15, so that the capacitor 3 which is thermally weak can be cooled by the coolant on the low-temperature side. In the case where the first side wall 10a2 and the third side wall 10b2 are joined to the other surface of the heatsink 6 by friction stirring, water-tightness of the cooling device 30 can be ensured.

In the case where the control board 1 electrically connected to the power semiconductor module 5 is provided so as to be opposed to the top surface 5b of the power semiconductor module 5 and the capacitor 3, the power conversion device 100 can be downsized and the inductance of the power conversion device 100 can be reduced. In the case where the power terminal 28 exposed to outside from the power semiconductor module 5 and the power terminal 29 exposed to outside from the capacitor 3 are electrically connected to each other between the control board 1, and the power semiconductor module 5 and the capacitor 3, the lengths of electric wires between the capacitor 3 and the power semiconductor module 5 can be minimized, whereby the inductance of the power conversion device 100 can be reduced.

### Second Embodiment

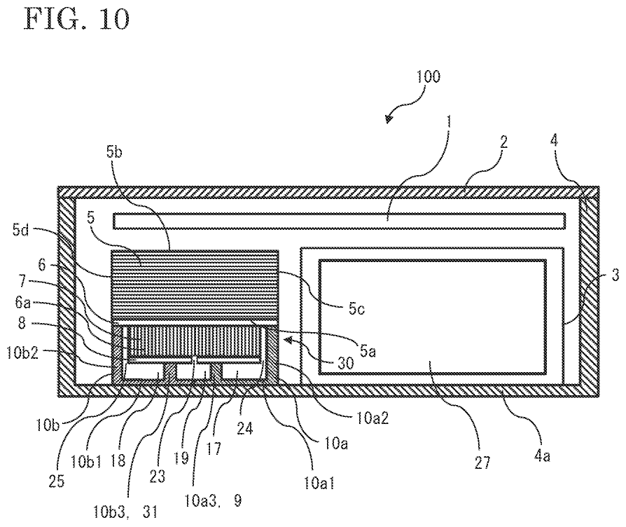

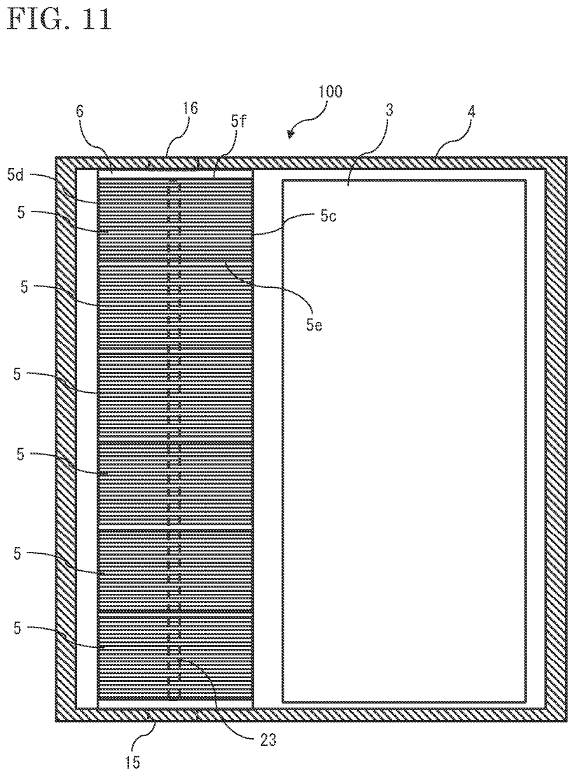

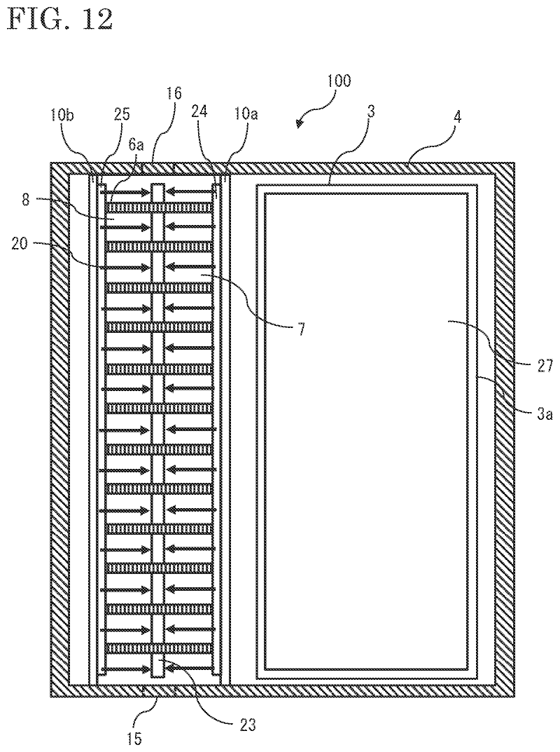

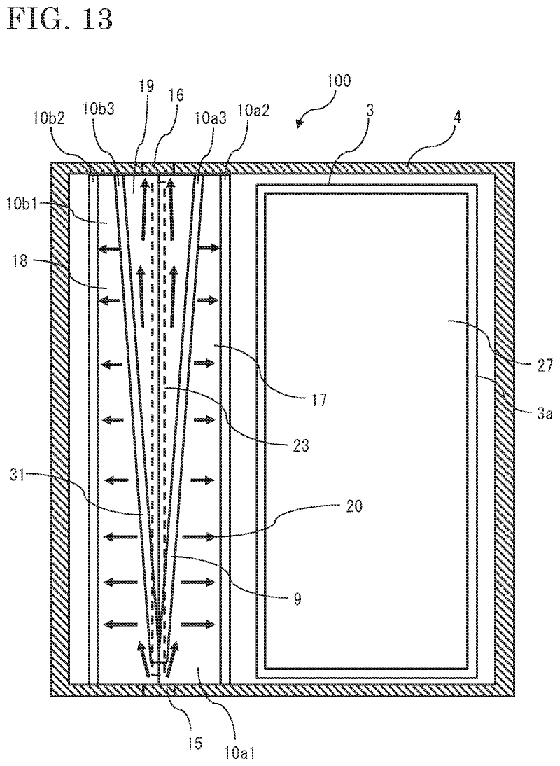

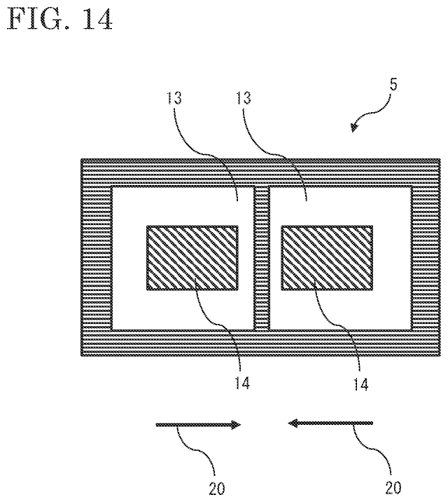

A power conversion device 100 according to the second embodiment of the present disclosure will be described. FIG. 10 is a sectional view schematically showing a specific part of the power conversion device 100 according to the second embodiment, FIG. 11 to FIG. 13 show other sectional views schematically showing specific parts of the power conversion device 100, and FIG. 14 schematically shows a structure of the power semiconductor module 5 of the power conversion device 100. FIG. 10 is a sectional view of the power conversion device 100 according to the second embodiment, taken at a position equal to the A-A cross-section position in FIG. 2. FIG. 11 is a sectional view of the power conversion device 100 according to the second embodiment, taken at a position equal to the B-B cross-section position in FIG. 3. FIG. 12 is a sectional view of the power conversion device 100 according to the second embodiment, taken at a position equal to the C-C cross-section position in FIG. 3. FIG. 13 is a sectional view of the power conversion device 100 according to the second embodiment, taken at a position equal to the D-D cross-section position in FIG. 3. In the power conversion device 100 according to the second embodiment, the structure of flow paths formed under the cooling flow path 7 in the cooling device 30 is different from that of the power conversion device 100 described in the first embodiment.

<Component Structure of Power Conversion Device 100>

As shown in FIG. 11, six power semiconductor modules 5 are arranged side by side in the direction parallel to the first side surfaces 5c so as to be directed in the same direction. The number of the power semiconductor modules 5 is not limited to six, and may be one. A penetration portion 23 represented by a broken line in FIG. 11 is provided in the first partition 8 at a position corresponding to the center of the six power semiconductor modules 5. In the present embodiment, as shown in FIG. 14, the power semiconductor module 5 is configured such that one power semiconductor 14 is mounted to each of two substrates 13 provided inside.

The cooling device 30 includes the heatsink 6, the cooling fins 6a, the first partition 8, the first water jacket 10a, the second water jacket 10b, the second partition 9, and a third partition 31. The second partition 9 is formed by a part of the first water jacket 10a, and the third partition 31 is formed by a part of the second water jacket 10b.

The first partition 8 has a plate shape, one surface thereof is opposed to the other surface of the heatsink 6 with the cooling fins 6a therebetween, and the penetration portion 23 is provided at a part between the first side surface 5c side and the second side surface 5d side. The first partition 8 is provided with a first penetration portion 24 along an end on the first side surface 5c side of the first partition 8, and a second penetration portion 25 along an end on the second side surface 5d side of the first partition 8. The second partition 9 has a plate shape. The second partition 9 extends from a part on the first side surface 5c side with respect to the penetration portion 23 on the other surface of the first partition 8, in a direction away from the other surface, and extends from the third side surface 5e side adjacent to the first side surface 5c of the power semiconductor module 5, to the fourth side surface 5f side opposite to the third side surface 5e side. The second partition 9 extends so as to approach the first side surface 5c side from the second side surface 5d side, as approaching the fourth side surface 5f side from the third side surface 5e side.

The third partition 31 has a plate shape. The third partition 31 extends from a part on the second side surface 5d side with respect to the penetration portion 23 on the other surface of the first partition 8, in a direction away from the other surface, and extends from the third side surface 5e side to the fourth side surface 5f side of the power semiconductor module 5. The third partition 31 extends so as to approach the second side surface 5d side from the first side surface 5c side, as approaching the fourth side surface 5f side from the third side surface 5e side. An end of the second partition 9 and an end of the third partition 31 are connected on the third side surface 5e side.

The first water jacket 10a has a quadrangular plate-shaped first bottom portion 10a1, a rectangular plate-shaped first side wall 10a2 extending from a first side surface of the first bottom portion 10a1 in the direction perpendicular to the plate surface of the first bottom portion 10a1, and a rectangular plate-shaped second side wall 10a3 having a smaller height than the first side wall 10a2 and extending from the plate surface of the first bottom portion 10a1 between the first side surface of the first bottom portion 10a1 and a second side surface of the first bottom portion 10a1 opposite to the first side surface, in the direction perpendicular to the plate surface of the first bottom portion 10a1, so as to be opposed to the first side wall 10a2. The second water jacket 10b has a quadrangular plate-shaped second bottom portion 10b1, a rectangular plate-shaped third side wall 10b2 extending from a first side surface of the second bottom portion 10b1 in the direction perpendicular to the plate surface of the second bottom portion 10b1, and a rectangular plate-shaped fourth side wall 10b3 having a smaller height than the third side wall 10b2 and extending from the plate surface of the second bottom portion 10b1 between the first side surface of the second bottom portion 10b1 and a second side surface of the second bottom portion 10b1 opposite to the first side surface, in the direction perpendicular to the plate surface of the second bottom portion 10b1, so as to be opposed to the third side wall 10b2. The second partition 9 is formed by the second side wall 10a3, and the third partition 31 is formed by the fourth side wall 10b3.

<Structure of Flow Path in Cooling Device 30>

As shown in FIG. 10, the flow path in the cooling device 30 is composed of the cooling flow path 7, a first flow path 17, a second flow path 18, and a third flow path 19. The cooling flow path 7 is provided above the first flow path 17, the second flow path 18, and the third flow path 19, and thus the flow path is formed in two stages.

The first flow path 17 extends from a first port which is the coolant inlet 15 and is provided on the third side surface 5e side, along the other surface of the first partition 8 and a surface of the second partition 9 on the first side surface 5c side, and is connected to a part on the first side surface 5c side of the cooling flow path 7. The cooling flow path 7 and the first flow path 17 are connected via the first penetration portion 24. The second flow path 18 extends from the first port, along the other surface of the first partition 8 and a surface of the third partition 31 on the second side surface 5d side, and is connected to a part on the second side surface 5d side of the cooling flow path 7. The cooling flow path 7 and the second flow path 18 are connected via the second penetration portion 25. The third flow path 19 extends from a second port which is the coolant outlet 16 and is provided on the side surface side opposite to the side surface side where the first port is provided, along the other surface of the first partition 8, a surface of the second partition 9 on the second side surface 5d side, and a surface of the third partition 31 on the first side surface 5c side, and is connected to the penetration portion 23. In the present embodiment, the capacitor 3 is provided on the first side surface 5c side, an end of the second partition 9 and an end of the third partition 31 are connected on the third side surface 5e side, and the second port is the coolant outlet 16. Thus, the capacitor 3 is close to the first flow path 17 through which the coolant flows in. The second partition 9 and the third partition 31 are arranged such that the first flow path 17 and the second flow path 18 are the same in the flow path length and the flow path width in which the coolant flows. Thus, the flow speeds of the branched coolants can be kept uniform.

As shown in FIG. 13, the coolant flows from the coolant inlet 15 so as to be branched into the first flow path 17 and the second flow path 18. In the first flow path 17, the second partition 9 extends so as to approach the first side surface 5c side from the second side surface 5d side, as approaching the fourth side surface 5f side from the third side surface 5e. Thus, the first flow path 17 is formed such that the sectional area thereof reduces in the direction in which the coolant flows. Also in the second flow path 18, the third partition 31 extends so as to approach the second side surface 5d side from the first side surface 5c side, as approaching the fourth side surface 5f side from the third side surface 5e side. Thus, the second flow path 18 is formed such that the sectional area thereof reduces in the direction in which the coolant flows. Therefore, the flow speed of the coolant is not slowed down even at a part far from the coolant inlet 15. The coolants flow from the first flow path 17 and the second flow path 18 into the cooling flow path 7 via the first penetration portion 24 and the second penetration portion 25. The coolants having passed between the cooling fins 6a are merged to flow from the cooling flow path 7 into the third flow path 19 via the penetration portion 23. The third flow path 19 is formed such that the sectional area thereof increases toward the coolant outlet 16. Therefore, the flow speed of the coolant is not slowed down even at a part far from the coolant outlet 16. The coolant having passed through the flow path in the cooling device 30 is discharged to outside from the coolant outlet 16. The temperature of the coolant flowing through the flow path in the cooling device 30 is low in the first flow path 17 and the second flow path 18 before the coolant passes through the cooling flow path 7, and is high in the third flow path 19 after the coolant passes through the cooling flow path 7. At the power semiconductor module 5, the flow directions 20 of the coolants are the directions of two arrows shown in FIG. 14.

With the above structure, the coolant can flow in the short-side direction of the entirety of the six power semiconductor modules 5, from the center to outer sides of the power semiconductor modules 5. Thus, increase in the fluid resistance can be suppressed, and therefore the occupation rate of the cooling fins 6a need not be decreased and the cooling fins 6a are arranged with a high density, so that heat dissipation of the power semiconductor modules 5 can be improved. The coolant flows in parallel with respect to each of the two substrates 13 provided in each of the six power semiconductor modules 5. Therefore, a temperature difference does not occur in each of the two substrates 13 among the six power semiconductor modules 5. Thus, heat dissipation of the substrates 13 of the six power semiconductor modules 5 can be uniformed irrespective of the locations. Since heat dissipation of the substrates 13 of the six power semiconductor modules 5 can be uniformed, electric characteristics of the substrates of the six power semiconductor modules 5 having temperature characteristics are uniformed among the six power semiconductor modules 5, whereby switching controllability of the power conversion device 100 can be improved.

Since the capacitor 3 is provided close to the first flow path 17 in which the temperature of the coolant is low, the capacitor 3 can be cooled at the initial temperature of the coolant flowing into the coolant inlet 15, so that the capacitor 3 which is thermally weak can be cooled by the coolant on the low-temperature side. The cooling flow path 7 is provided above the first flow path 17, the second flow path 18, and the third flow path 19, and the power semiconductor modules 5 are provided above the cooling flow path 7, so that there are no flow paths around the side surfaces of the power semiconductor modules 5. Therefore, the capacitor 3 can be provided close to the power semiconductor modules 5. Since the capacitor 3 can be provided close to the power semiconductor modules 5, the power semiconductor modules 5 and the capacitor 3 can be wired by metal bus bars with the shortest distance. Thus, the parasitic inductances on the metal bus bars are reduced, whereby the power semiconductors 14 of the power semiconductor modules 5 can perform high-speed switching operations.

In the present embodiment, the first port is the coolant inlet 15, and the second port is the coolant outlet 16. However, without limitation thereto, the first port may be the coolant outlet 16, and the second port may be the coolant inlet 15. In addition, the second partition 9 may extend so as to approach the second side surface 5d side from the first side surface 5c side, as approaching the fourth side surface 5f side from the third side surface 5e side, the third partition 31 may extend so as to approach the first side surface 5c side from the second side surface 5d side, as approaching the fourth side surface 5f side from the third side surface 5e side, and an end of the second partition 9 and an end of the third partition 31 may be connected on the fourth side surface 5f side.

As described above, the power conversion device 100 according to the second embodiment includes: the cooling flow path 7 through which the coolant flows in the direction perpendicular to the first side surface 5c of the power semiconductor module 5, in a space between the other surface of the heatsink 6 and the one surface of the first partition 8; the first flow path 17 extending from the first port which is the coolant inlet 15, along the other surface of the first partition 8 and the surface of the second partition 9 on the first side surface 5c side, and connected to a part on the first side surface 5c side of the cooling flow path 7; the second flow path 18 extending from the first port along the other surface of the first partition 8 and the surface of the third partition 31 on the second side surface 5d side, and connected to a part of the cooling flow path 7 on the second side surface 5d side; and the third flow path 19 extending from the second port which is the coolant outlet 16, along the other surface of the first partition 8, the surface of the second partition 9 on the second side surface 5d side, and the surface of the third partition 31 on the first side surface 5c side, and connected to the penetration portion 23, wherein the length on the first side surface 5c side of the power semiconductor module 5 is greater than the length on the third side surface 5e side thereof. Thus, the coolant flows in the short-side direction of the power semiconductor module 5, so that the fluid resistance in the cooling flow path 7 is reduced. Therefore, it is possible to increase the occupation rate of the cooling fins 6a and improve heat dissipation of the power semiconductor module 5.

In the case where the second partition 9 is formed by a part of the first water jacket 10a, the third partition 31 is formed by a part of the second water jacket 10b, and the first flow path 17, the second flow path 18, and the third flow path 19 are formed by the first water jacket 10a and the second water jacket 10b, productivity of the power conversion device 100 can be improved and the power conversion device 100 can be manufactured at low cost. In addition, since the coolant flows in the short-side direction from the center to outer sides of the power semiconductor module 5, heat dissipation of the power semiconductor module 5 can be uniformed irrespective of locations on the power semiconductor module 5. In addition, in the case where the power semiconductor module 5 has two substrates 13 along the direction in which the coolant flows, a temperature difference does not occur in each of the two substrates 13. Therefore, electric characteristics of the respective substrates of the power semiconductor module 5 having temperature characteristics are uniformed in the power semiconductor module 5, whereby switching controllability of the power conversion device 100 can be improved.

In the case where the capacitor 3 is provided on the first side surface 5c side, an end of the second partition 9 and an end of the third partition 31 are connected on the third side surface 5e side, and the second port is the coolant outlet 16, the capacitor 3 is provided close to the first flow path 17 in which the temperature of the coolant is low, whereby the capacitor 3 can be cooled at the initial temperature of the coolant flowing into the coolant inlet 15, so that the capacitor 3 which is thermally weak can be cooled by the coolant on the low-temperature side.

### Third Embodiment

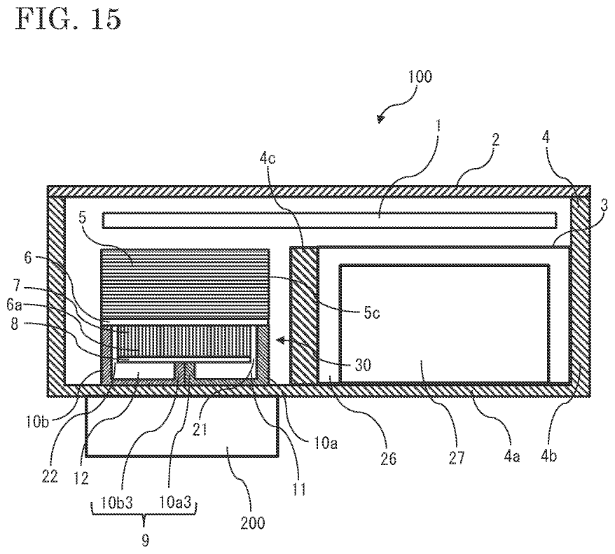

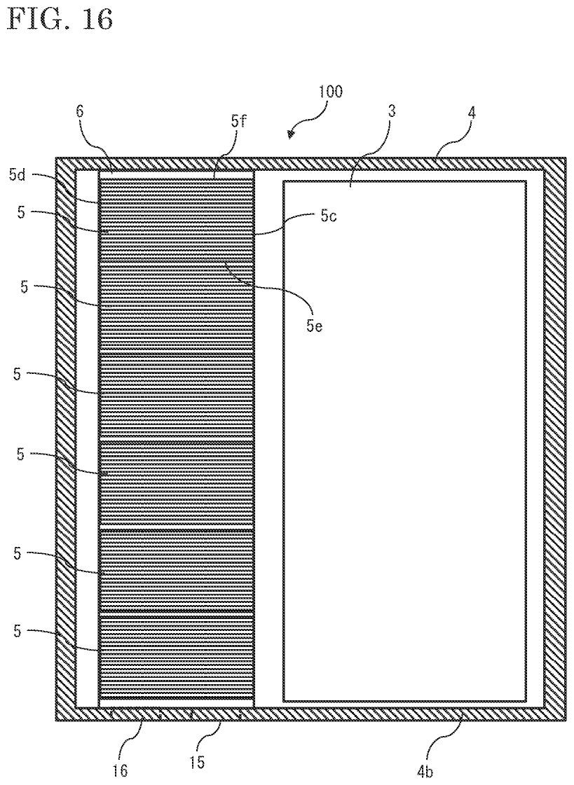

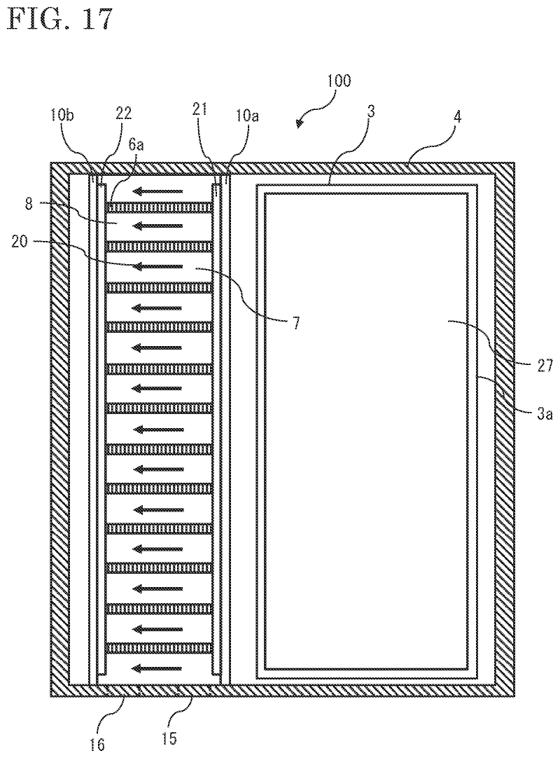

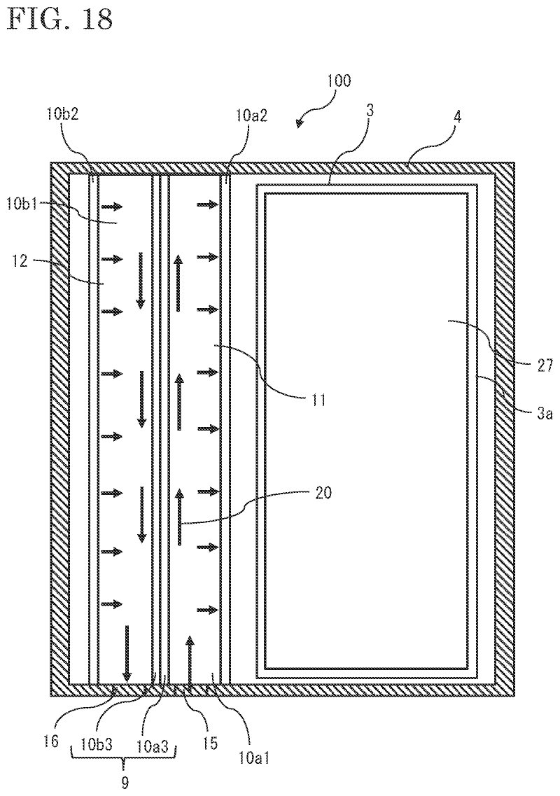

A power conversion device 100 according to the third embodiment of the present disclosure will be described. FIG. 15 is a sectional view schematically showing a specific part of the power conversion device 100 according to the third embodiment, and FIG. 16 to FIG. 18 are other sectional views schematically showing specific parts of the power conversion device 100. FIG. 15 is a sectional view of the power conversion device 100 according to the third embodiment, taken at a position equal to the A-A cross-section position in FIG. 2. FIG. 16 is a sectional view of the power conversion device 100 according to the third embodiment, taken at a position equal to the B-B cross-section position in FIG. 3. FIG. 17 is a sectional view of the power conversion device 100 according to the third embodiment, taken at a position equal to the C-C cross-section position in FIG. 3. FIG. 18 is a sectional view of the power conversion device 100 according to the third embodiment, taken at a position equal to the D-D cross-section position in FIG. 3. In the power conversion device 100 according to the third embodiment, arrangement of the second partition 9 and the position of the coolant outlet 16 in the cooling device 30 are different from those in the power conversion device 100 described in the first embodiment.

<Component Structure of Power Conversion Device 100>

As shown in FIG. 16, six power semiconductor modules 5 are arranged side by side in the direction parallel to the first side surfaces 5c so as to be directed in the same direction. In the power semiconductor module 5, for example, as shown in FIG. 8, two power semiconductors 14 are mounted to one substrate 13 provided inside. The coolant inlet 15 through which the coolant flows in and the coolant outlet 16 through which the coolant flows out are both provided in the side portion 4b of the case 4 on the third side surface 5e side of the power semiconductor module 5.

As shown in FIG. 15, the case 4 has a partition wall 4c extending in the perpendicular direction from the plate surface of the bottom plate 4a. The element component 27 which is an element part of the capacitor 3 is provided in the internal space surrounded by the partition wall 4c and the side portions 4b, and the element component 27 is fixed to the case 4 with a potting material 26 therebetween. The capacitor 3 is provided on the first side surface 5c side. The power conversion device 100 is provided with a second power conversion device 200. The second power conversion device 200 is attached to a part of a surface of the bottom plate 4a of the case 4 opposite to a part of a surface of the bottom plate 4a to which the first water jacket 10a and the second water jacket 10b are attached. The inflow path 11 and the outflow path 12 formed by the first water jacket 10a and the second water jacket 10b are thermally connected to the second power conversion device 200, and thus the second power conversion device 200 is cooled by the coolant flowing through these flow paths.

The cooling device 30 includes the heatsink 6, the cooling fins 6a, the first partition 8, the first water jacket 10a, the second water jacket 10b, and the second partition 9. The second partition 9 is formed by a part of the first water jacket 10a and a part of the second water jacket 10b. As shown in FIG. 18, the second partition 9 extends in parallel to the first side surfaces 5c from the third side surface 5e side between the coolant inlet 15 and the coolant outlet 16 to the fourth side surface 5f side.

<Structure of Flow Path in Cooling Device 30>

As shown in FIG. 15, the flow path in the cooling device 30 is composed of the cooling flow path 7, the inflow path 11, and the outflow path 12. The cooling flow path 7 is provided above the inflow path 11 and the outflow path 12, and thus the flow path is formed in two stages. The inflow path 11 and the outflow path 12 are the same in the flow path length and the flow path width. As shown in FIG. 18, the coolant flows from the coolant inlet 15 into the inflow path 11. As shown in FIG. 17, the coolant flows from the inflow path 11 into the cooling flow path 7 via the inflow penetration portion 21. The coolant having passed between the cooling fins 6a flows from the cooling flow path 7 into the outflow path 12 via the outflow penetration portion 22. The coolant having passed through the flow path in the cooling device 30 is discharged to outside from the coolant outlet 16. The coolant flows in parallel among the six power semiconductor modules 5. The temperature of the coolant flowing through the flow path in the cooling device 30 is low in the inflow path 11 before the coolant passes through the cooling flow path 7, and is high in the outflow path 12 after the coolant passes through the cooling flow path 7. One or both of the coolant inlet 15 and the coolant outlet 16 may be provided on the fourth side surface 5f side.

As described above, in the power conversion device 100 according to the third embodiment, the second partition 9 extends in parallel to the first side surface 5c from the third side surface 5e side to the fourth side surface 5f side and thus the coolant inlet 15 and the coolant outlet 16 are both provided on the third side surface 5e side of the power semiconductor module 5, whereby the degree of freedom in the layout of the coolant inlet 15 and the coolant outlet 16 can be improved. The second power conversion device 200 is attached to a part of a surface of the bottom plate 4a of the case 4 opposite to a part of a surface of the bottom plate 4a to which the first water jacket 10a and the second water jacket 10b are attached. Thus, the second power conversion device 200 can be cooled by the cooling device 30 provided in the power conversion device 100. In addition, since the second power conversion device 200 is cooled by the cooling device 30 of the power conversion device 100, another cooling device is not needed for the second power conversion device 200, so that the second power conversion device 200 can be downsized. In addition, the second partition 9 functions as a cooling fin for the second power conversion device 200, whereby the cooling performance of the second power conversion device 200 can be improved.

The element component 27 of the capacitor 3 is provided in the internal space surrounded by the side portions 4b and the partition wall 4c extending in the perpendicular direction from the plate surface of the bottom plate 4a of the case 4, and the element component 27 is fixed to the case 4 with the potting material 26 therebetween. Therefore, the capacitor case 3a is not needed and there is no contact interface between the element component 27 and the case 4, so that the contact thermal resistance is reduced and heat dissipation of the element component 27 is increased, whereby the life of the element component 27 can be improved. In addition, the first partition 8 provided between the power semiconductor module 5 and the second power conversion device 200 serves as a heat shielding plate, so that the power semiconductor module 5 and the second power conversion device 200 are prevented from thermally interfering with each other and the power semiconductor module 5 and the second power conversion device 200 can be efficiently cooled.

In the above description, the case where the power conversion device 100 outputs three-phase AC currents has been shown. However, the power conversion device 100 may be various types of power conversion devices such as a DC-DC converter, and the capacitor 3 may be provided at each part that requires smoothing, e.g., the output side connected to a load. In addition, a part to which the capacitor 3 is connected is not limited to the power semiconductor module 5, but may be the substrate having the power semiconductor 14, for example.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 control board

2 cover

3 capacitor

3a capacitor case

4 case

4a bottom plate

4b side portion

4c partition wall

5 power semiconductor module

5a bottom surface

5b top surface

5c first side surface

5d second side surface

5e third side surface

5f fourth side surface

6 heatsink

6a cooling fin

7 cooling flow path

8 first partition

9 second partition

10a first water jacket

10a1 first bottom portion

10a2 first side wall

10a3 second side wall

10b second water jacket

10b1 second bottom portion

10b2 third side wall

10b3 fourth side wall

11 inflow path

12 outflow path

13 substrate

14 power semiconductor

15 coolant inlet

16 coolant outlet

17 first flow path

18 second flow path

19 third flow path

20 flow direction

21 inflow penetration portion

22 outflow penetration portion

23 penetration portion

24 first penetration portion

25 second penetration portion

26 potting material

27 element component

28 power terminal

29 power terminal

30 cooling device

31 third partition

50 housing

100 power conversion device

101 upper arm

102 lower arm

200 second power conversion device

What is claimed is:

1. A power conversion device comprising:
a power semiconductor module including a power semiconductor, the power semiconductor module being formed in a rectangular parallelepiped shape and having a bottom surface, a top surface, and four side surfaces;
a capacitor electrically connected to the power semiconductor module, and provided on a first side surface side of the power semiconductor module or on a second side surface side thereof opposite to the first side surface;
a plate-shaped heatsink whose one surface is thermally connected to the bottom surface of the power semiconductor module;
a cooling fin provided to another surface of the heatsink;
a plate-shaped first partition provided such that one surface thereof is opposed to the other surface of the heatsink with the cooling fin therebetween;
a cooling flow path through which a coolant flows in a direction perpendicular to the first side surface, in a space in which the cooling fin is placed between the other surface of the heatsink and the one surface of the first partition;
a plate-shaped second partition extending from another surface of the first partition in a direction away from the other surface, and extending from a third side surface side adjacent to the first side surface of the power semiconductor module, to a fourth side surface side thereof opposite to the third side surface;
an inflow path extending from a coolant inlet provided on the third side surface side or the fourth side surface side, along the other surface of the first partition and a surface of the second partition on the first side surface side, the inflow path being connected to a part on the first side surface side of the cooling flow path; and
an outflow path extending from a coolant outlet provided on the third side surface side or the fourth side surface side, along the other surface of the first partition and a surface of the second partition on the second side surface side, the outflow path being connected to a part on the second side surface side of the cooling flow path, wherein
a length of the first side surface of the power semiconductor module is greater than a length of the third side surface thereof.

2. A power conversion device comprising:
a power semiconductor module including a power semiconductor, the power semiconductor module being formed in a rectangular parallelepiped shape and having a bottom surface, a top surface, and four side surfaces;
a capacitor electrically connected to the power semiconductor module, and provided on a first side surface side of the power semiconductor module or on a second side surface side thereof opposite to the first side surface;
a plate-shaped heatsink whose one surface is thermally connected to the bottom surface of the power semiconductor module;
a cooling fin provided to another surface of the heatsink;
a plate-shaped first partition provided such that one surface thereof is opposed to the other surface of the heatsink with the cooling fin therebetween, the first partition having a penetration portion at a part between the first side surface side and the second side surface side;
a cooling flow path through which a coolant flows in a direction perpendicular to the first side surface, in a space in which the cooling fin is placed between the other surface of the heatsink and the one surface of the first partition;
a plate-shaped second partition extending from a part on the first side surface side with respect to the penetration portion on the other surface of the first partition, in a direction away from the other surface, and extending from a third side surface side adjacent to the first side surface of the power semiconductor module, to a fourth side surface side thereof opposite to the third side surface;
a plate-shaped third partition extending from a part on the second side surface side with respect to the penetration portion on the other surface of the first partition, in a direction away from the other surface, and extending from the third side surface side to the fourth side surface side;
a first flow path extending from a first port which is a coolant inlet or a coolant outlet and is provided on the third side surface side or the fourth side surface side, along the other surface of the first partition and a surface of the second partition on the first side surface side, the first flow path being connected to a part on the first side surface side of the cooling flow path;
a second flow path extending from the first port along the other surface of the first partition and a surface of the third partition on the second side surface side, the second flow path being connected to a part on the second side surface side of the cooling flow path; and
a third flow path extending from a second port which is the coolant inlet or the coolant outlet and is provided on a side surface side opposite to the side surface side on which the first port is provided, along the other surface of the first partition, a surface of the second partition on the second side surface side, and a surface of the third partition on the first side surface side, the third flow path being connected to the penetration portion, wherein
an end of the second partition and an end of the third partition are connected to each other on the third side surface side or the fourth side surface side, and
a length of the first side surface of the power semiconductor module is greater than a length of the third side surface thereof.

3. The power conversion device according to claim 1, further comprising a plurality of the power semiconductor modules whose bottom surfaces are thermally connected to the one surface of the heatsink, the plurality of the power semiconductor modules being arranged side by side together with the power semiconductor module in a direction parallel to the first side surface so as to be directed in the same direction as the power semiconductor module, wherein
the capacitor is provided on the first side surface side or the second side surface side of the plurality of power semiconductor modules so as to be opposed to the first side surfaces or the second side surfaces of the plurality of the power semiconductor modules, and
a length on the first side surface side of the plurality of power semiconductor modules is greater than a length on the third side surface side thereof.

4. The power conversion device according to claim 2, further comprising a plurality of the power semiconductor modules whose bottom surfaces are thermally connected to the one surface of the heatsink, the plurality of the power semiconductor modules being arranged side by side together with the power semiconductor module in a direction parallel to the first side surface so as to be directed in the same direction as the power semiconductor module, wherein
the capacitor is provided on the first side surface side or the second side surface side of the plurality of power semiconductor modules so as to be opposed to the first side surfaces or the second side surfaces of the plurality of the power semiconductor modules, and
a length on the first side surface side of the plurality of power semiconductor modules is greater than a length on the third side surface side thereof.

5. The power conversion device according to claim 1, further comprising:
an inflow penetration portion provided along an end on the first side surface side of the first partition; and
an outflow penetration portion provided along an end on the second side surface side of the first partition, wherein
the cooling flow path and the inflow path are connected to each other via the inflow penetration portion, and the cooling flow path and the outflow path are connected to each other via the outflow penetration portion,
the coolant inlet is provided on the third side surface side, and the coolant outlet is provided on the fourth side surface, and
the second partition extends so as to approach the first side surface side from the second side surface side, as approaching the fourth side surface side from the third side surface side.

6. The power conversion device according to claim 2, further comprising:
a first penetration portion provided along an end on the first side surface side of the first partition; and
a second penetration portion provided along an end on the second side surface side of the first partition, wherein
the cooling flow path and the first flow path are connected to each other via the first penetration portion, and the cooling flow path and the second flow path are connected to each other via the second penetration portion,
the first port is provided on the third side surface side, and the second port is provided on the fourth side surface side,
the second partition extends so as to approach the first side surface side from the second side surface side, as approaching the fourth side surface side from the third side surface,
the third partition extends so as to approach the second side surface side from the first side surface, as approaching the fourth side surface side from the third side surface side, and
the end of the second partition and the end of the third partition are connected to each other on the third side surface side.

7. The power conversion device according to claim 1, further comprising:
an inflow penetration portion provided along an end on the first side surface side of the first partition; and
an outflow penetration portion provided along an end on the second side surface side of the first partition, wherein
the cooling flow path and the inflow path are connected to each other via the inflow penetration portion, and the cooling flow path and the outflow path are connected to each other via the outflow penetration portion,
the coolant inlet and the coolant outlet are provided on the third side surface side, and
the second partition extends in parallel to the first side surface, from the third side surface side between the coolant inlet and the coolant outlet to the fourth side surface side.

8. The power conversion device according to claim 1, further comprising:
a first water jacket having a quadrangular plate-shaped first bottom portion, a rectangular plate-shaped first side wall extending from a first side surface of the first bottom portion in a direction perpendicular to a plate surface of the first bottom portion, and a rectangular plate-shaped second side wall having a smaller height than the first side wall and extending from a second side surface of the first bottom portion opposite to the first side surface thereof, in the direction perpendicular to the plate surface of the first bottom portion, so as to be opposed to the first side wall; and
a second water jacket having a quadrangular plate-shaped second bottom portion, a rectangular plate-shaped third side wall extending from a first side surface of the second bottom portion in a direction perpendicular to a plate surface of the second bottom portion, and a rectangular plate-shaped fourth side wall having a smaller height than the third side wall and extending from a second side surface of the second bottom portion opposite to the first side surface thereof, in the direction perpendicular to the plate surface of the second bottom portion, so as to be opposed to the third side wall, wherein
outer wall surfaces of both of the second side wall and the fourth side wall are in contact with each other so that the second partition is formed by the second side wall and the fourth side wall,
a side surface of the second side wall opposite to a side surface thereof on the first bottom portion side, and a side surface of the fourth side wall opposite to a side surface thereof on the second bottom portion side, are joined to the other surface of the first partition, and
a side surface of the first side wall opposite to a side surface thereof on the first bottom portion side, and a side surface of the third side wall opposite to a side surface thereof on the second bottom portion side, are joined to the other surface of the heatsink.

9. The power conversion device according to claim 2, further comprising:
a first water jacket having a quadrangular plate-shaped first bottom portion, a rectangular plate-shaped first side wall extending from a first side surface of the first bottom portion in a direction perpendicular to a plate surface of the first bottom portion, and a rectangular plate-shaped second side wall having a smaller height than the first side wall and extending from the plate surface of the first bottom portion between the first side surface of the first bottom portion and a second side surface of the first bottom portion opposite to the first side surface, in the direction perpendicular to the plate surface of the first bottom portion, so as to be opposed to the first side wall; and
a second water jacket having a quadrangular plate-shaped second bottom portion, a rectangular plate-shaped third side wall extending from a first side surface of the second bottom portion in a direction perpendicular to a plate surface of the second bottom portion, and a rectangular plate-shaped fourth side wall having a smaller height than the third side wall and extending from the plate surface of the second bottom portion between the first side surface of the second bottom portion and a second side surface of the second bottom portion opposite to the first side surface, in the direction perpendicular to the plate surface of the second bottom portion, so as to be opposed to the third side wall, wherein
the second partition is formed by the second side wall, and the third partition is formed by the fourth side wall,
a side surface of the second side wall opposite to a side surface thereof on the first bottom portion side, and a side surface of the fourth side wall opposite to a side surface thereof on the second bottom portion side, are joined to the other surface of the first partition, and
a side surface of the first side wall opposite to a side surface thereof on the first bottom portion side, and a side surface of the third side wall opposite to a side surface thereof on the second bottom portion side, are joined to the other surface of the heatsink.

10. The power conversion device according to claim 8, further comprising a case having a rectangular plate-shaped bottom plate and side portions extending from four side surfaces of the bottom plate in a direction perpendicular to a plate surface of the bottom plate, the case storing the first water jacket, the second water jacket, the first partition, the heatsink, the power semiconductor module, and the capacitor, wherein
the first bottom portion of the first water jacket, the second bottom portion of the second water jacket, and the capacitor are attached to the bottom plate of the case.

11. The power conversion device according to claim 9, further comprising a case having a rectangular plate-shaped bottom plate and side portions extending from four side surfaces of the bottom plate in a direction perpendicular to a plate surface of the bottom plate, the case storing the first water jacket, the second water jacket, the first partition, the heatsink, the power semiconductor module, and the capacitor, wherein
the first bottom portion of the first water jacket, the second bottom portion of the second water jacket, and the capacitor are attached to the bottom plate of the case.

12. The power conversion device according to claim 1, wherein
the capacitor is provided on the first side surface side on which the inflow path is provided.

13. The power conversion device according to claim 6, wherein
the second port is the coolant outlet.

14. The power conversion device according to claim 8, wherein
the first side wall and the third side wall are joined to the other surface of the heatsink by friction stirring.

15. The power conversion device according to claim 9, wherein
the first side wall and the third side wall are joined to the other surface of the heatsink by friction stirring.

16. The power conversion device according to claim 1, further comprising a control board for controlling operation of the power semiconductor module, wherein
the control board electrically connected to the power semiconductor module is provided so as to be opposed to the top surface of the power semiconductor module and the capacitor.

17. The power conversion device according to claim 16, wherein
a power terminal exposed to outside from the power semiconductor module and a power terminal exposed to outside from the capacitor are electrically connected to each other, between the control board, and the power semiconductor module and the capacitor.

18. The power conversion device according to claim 10, further comprising a second power conversion device, wherein
the second power conversion device is attached to a part of a surface of the bottom plate of the case opposite to a part of a surface of the bottom plate to which the first water jacket and the second water jacket are attached.

19. The power conversion device according to claim 10, wherein
the case has a partition wall extending in the perpendicular direction from the plate surface of the bottom plate, and
an element part of the capacitor is placed in an internal space surrounded by the partition wall and the side portions, and the element part is fixed to the case with a potting material therebetween.
